(19) United States
(12) Patent Application Publication
(10) Pub. No.: US 2025/0386687 A1
(43) Pub. Date: Dec. 18, 2025

(54) DISPLAY DEVICE AND METHOD OF MANUFACTURING THE SAME

(71) Applicant: Samsung Display Co., LTD., Yongin-si (KR)

(72) Inventor: Hyun Eok SHIN, Yongin-si (KR)

(21) Appl. No.: 19/023,059

(22) Filed: Jan. 15, 2025

(30) Foreign Application Priority Data
Jun. 18, 2024 (KR) 10-2024-0079044

(51) Int. Cl. H10K 59/131; H10D 86/40; H10D 86/60; H10K 59/121; H10K 59/122; H10K 102/00; H10K 102/10

(52) U.S. Cl. CPC H10K 59/131; H10K 59/1213; H10K 59/122; H10D 86/441; H10D 86/60; H10K 2102/103; H10K 2102/321

(57) ABSTRACT

A display device includes a pixel circuit including a transistor on a substrate, a first cathode electrode electrically connected to the pixel circuit and in a first emission area, a first electron transporting layer on the first cathode electrode, an insulating layer covering an edge of the first electron transporting layer, a first light emitting layer on the first electron transporting layer and the insulating layer, a first hole transporting layer on the first light emitting layer, a first anode electrode on the first hole transporting layer, a first bank on the insulating layer, surrounding the first emission area and in contact with the first anode electrode, and a second bank on the first bank and including a tip protruding from a side surface of the first bank toward the first emission area.

### CROSS-REFERENCE TO RELATED APPLICATION

The present application claims priority to and the benefit of Korean Patent Application No. 10-2024-0079044, filed on Jun. 18, 2024, in the Korean Intellectual Property Office, the entire disclosure of which is incorporated herein by reference.

### BACKGROUND

### 1. Field

Aspects of embodiments of the present disclosure relate to a display device and a method of manufacturing the same.

### 2. Description of the Related Art

As the information society develops, demand for various forms of display devices for displaying images is increasing. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element that enables each pixel of a display panel to emit light by itself. Thus, the light emitting display device can display an image without a backlight unit that provides light to the display panel.

The above information disclosed in this Background section is only for enhancement of understanding of the background of the invention and therefore it may contain information that does not form the prior art.

### SUMMARY

Aspects of some embodiments of the present disclosure are directed to a display device having an inverted pixel structure to reduce the deterioration of the light emitting element and reduce (minimize) product afterimages, and a method of manufacturing the display device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

Details of other embodiments are included in the detailed description and drawings. According to some embodiments of the present disclosure, there is provided a display device including: a pixel circuit including a transistor on a substrate; a first cathode electrode electrically connected to the pixel circuit and in a first emission area; a first electron transporting layer on the first cathode electrode; an insulating layer covering an edge of the first electron transporting layer; a first light emitting layer on the first electron transporting layer and the insulating layer; a first hole transporting layer on the first light emitting layer; a first anode electrode on the first hole transporting layer; a first bank on the insulating layer, surrounding the first emission area and in contact with the first anode electrode; and a second bank on the first bank and including a tip protruding from a side surface of the first bank toward the first emission area.

In some embodiments, the first anode electrode may receive a driving voltage through the first bank.

In some embodiments, the display device may further include: a first capping layer on the first anode electrode; and a first inorganic layer covering an upper surface of the first capping layer, the side surface of the first bank, and the lower and side surfaces of the tip of the second bank.

In some embodiments, the first inorganic layer may have a cavity structure spaced apart from the upper surface of the second bank.

In some embodiments, the first electron transporting layer may include ytterbium (Yb) or zinc (Zn), and the first hole transporting layer may include nickel (Ni).

In some embodiments, the first cathode electrode may be a reflective electrode including material having a high reflectivity, and the first anode electrode may be translucent or transparent.

In some embodiments, the display device may further include: a second cathode electrode in a second emission area of the substrate; a second electron transporting layer on the second cathode electrode; a second light emitting layer on the second electron transporting layer; a second hole transporting layer on the second light emitting layer; and a second anode electrode on the second hole transporting layer to be in contact with the side surface of the first bank.

In some embodiments, the first and second anode electrodes may be electrically connected through the first bank to receive a driving voltage.

In some embodiments, the display device may further include: a second capping layer on the second anode electrode; and a second inorganic layer covering the upper surface of the second capping layer, and the lower and side surfaces of the tip of the second bank.

In some embodiments, the display device may further include: a third cathode electrode in a third emission area of the substrate; a third electron transporting layer on the third cathode electrode; a third light emitting layer on the third electron transporting layer; a third hole transporting layer on the third light emitting layer; and a third anode electrode on the third hole transporting layer to be in contact with the side surface of the first bank.

In some embodiments, the pixel circuit may include: an active region, a drain electrode, and a source electrode of the transistor on the substrate; a gate electrode of the transistor in the active region of the transistor; a first connection electrode on the gate electrode and connected to the drain electrode of the transistor; and a second connection electrode on the first connection electrode and electrically connecting the first cathode electrode and the first connection electrode.

In some embodiments, the pixel circuit may include: a well area of a pixel transistor on a top portion of a semiconductor substrate; a drain area on a first side of the well area; a source area on a second side of the well area; a channel area between the drain area and the source area; a first low concentration impurity area between the channel area and the source area; a second low concentration impurity area between the channel area and the drain area; a contact terminal connected to the source area; and a metal layer electrically connecting the contact terminal and the first cathode electrode.

According to some embodiments of the disclosure, there is provided a method of manufacturing a display device, the method including: forming a first cathode electrode overlapping with a first emission area and a second cathode electrode overlapping with a second emission area on a substrate; forming a first electron transporting layer on the first cathode electrode, and forming a second electron transporting layer on the second cathode electrode; sequentially stacking a sacrificial layer, an insulating layer, a first bank, and a second bank on the first and second electron transporting layers; etching the second bank and the first bank to form a tip of the second bank protruding from a side surface of the first bank; etching the insulating layer and the sacrificial layer to expose the first and second electron transporting layer; forming a first light emitting layer on the first electron transporting layer and forming a first organic pattern in an area excluding the first electron transporting layers; forming a first hole transporting layer on the first light emitting layer and forming a first hole pattern on the first organic pattern; and forming a first anode electrode in contact with the side surface of the first bank on the first hole transporting layer and forming a first electrode pattern on the first hole pattern.

In some embodiments, the first electron transporting layer may include ytterbium (Yb) or zinc (Zn), and the first hole transporting layer may include nickel (Ni).

In some embodiments, the first cathode electrode may be a reflective electrode containing material having a high reflectivity, and the first anode electrode may be transparent or translucent.

In some embodiments, the method may further include: forming a first capping layer on the first anode electrode and forming a first capping pattern on the first electrode pattern; and forming a first inorganic layer covering the upper surface of the first capping layer, the side surface of the first bank, and the lower and side surfaces of the tip of the second bank.

In some embodiments, the method may further include etching the first inorganic layer, the first capping pattern, the first electrode pattern, the first hole pattern, and the first organic pattern not overlapping the first emission area.

In some embodiments, the method may further include: forming a second light emitting layer on the second electron transporting layer; forming a second hole transporting layer on the second light emitting layer; forming a second anode electrode in contact with the side surface of the first bank on the second hole transporting layer; forming a second capping layer on the second anode electrode; and forming a second inorganic layer covering the upper surface of the second capping layer, the side surface of the first bank, and the lower and the side surfaces of the tip of the second bank.

In some embodiments, the first and second anode electrodes and the first bank may be electrically connected.

In some embodiments, the method may further include: forming a third cathode electrode overlapping a third emission area on the substrate; forming a third electron transporting layer on the third cathode electrode; forming a third light emitting layer on the third electron transporting layer; forming a third hole transporting layer on the third hole transporting layer; forming a third anode electrode in contact with the side surface of the first bank on the third hole transporting layer; forming a third capping layer on the third anode electrode; and forming a third inorganic layer covering the upper surface of the third capping layer, the side surface of the first bank, and the lower and side surfaces of the tip of the second bank.

According to some embodiments of the disclosure, there is provided an electronic device including: a display device including: a pixel circuit including a transistor on a substrate; a first cathode electrode electrically connected to the pixel circuit and in a first emission area; a first electron transporting layer on the first cathode electrode; an insulating layer covering an edge of the first electron transporting layer; a first light emitting layer on the first electron transporting layer and the insulating layer; a first hole transporting layer on the first light emitting layer; a first anode electrode on the first hole transporting layer; a first bank on the insulating layer, surrounding the first emission area and in contact with the first anode electrode; and a second bank on the first bank and including a tip protruding from a side surface of the first bank toward the first emission area; and a housing configured to receive the display device.

According to some embodiments of the disclosure, there is provided a head-mounted electronic device including: a display device including: a pixel circuit including a transistor on a substrate; a first cathode electrode electrically connected to the pixel circuit and in a first emission area; a first electron transporting layer on the first cathode electrode; an insulating layer covering an edge of the first electron transporting layer; a first light emitting layer on the first electron transporting layer and the insulating layer; a first hole transporting layer on the first light emitting layer; a first anode electrode on the first hole transporting layer; a first bank on the insulating layer, surrounding the first emission area and in contact with the first anode electrode; and a second bank on the first bank and including a tip protruding from a side surface of the first bank toward the first emission area, and a head mounted display including: a first lens array; a second lens array; and a display panel housing configured to receive the display device, wherein the first and second lens arrays are configured to display an image of the display device to each of a user's eyes.

However, effects according to the embodiments of the present disclosure are not limited to those exemplified above and various other effects are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to some embodiments of the present disclosure;

FIG. 2 is a cross-sectional view of the display device according to some embodiments of the present disclosure;

FIG. 3 is a plan view of a display unit of the display device according to some embodiments of the present disclosure;

FIG. 4 is a schematic drawing of a pixel of the display device according to some embodiments of the present disclosure;

FIG. 5 is a cross-sectional view illustrating pixels of the display device according to some embodiments of the present disclosure;

FIG. 6 is an enlarged view of area A1 of FIG. 5 according to some embodiments of the present disclosure;

FIGS. 7 to 13 are cross-sectional views illustrating a process of manufacturing a display device according to some embodiments of the present disclosure;

FIG. 14 illustrates a virtual reality device including a display device according to some embodiments of the present disclosure;

FIGS. 15 and 16 illustrate a head mounted display including a display device according to some embodiments of the present disclosure; and

FIG. 17 is a cross-sectional view illustrating pixels in the display devices of FIGS. 14 through 16 according to some embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

1 As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. The electronic or electric devices and/or any other relevant devices or

components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

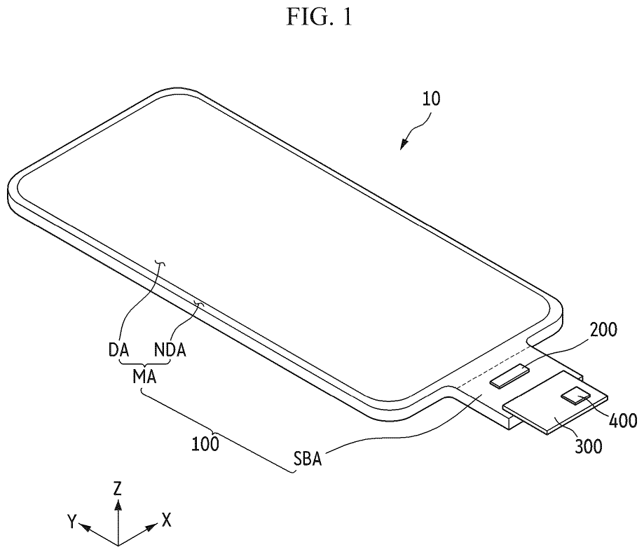

FIG. 1 is a perspective view of a display device according to some embodiments of the present disclosure.

Referring to FIG. 1, a display device 10 may be applied to portable electronic devices, such as mobile phones, smartphones, tablet personal computers (PCs), mobile communication terminals, electronic notebooks, electronic books, portable multimedia players (PMPs), navigation devices, ultra-mobile PCs (UMPCs), and the like. For example, the display device 10 may be applied as a display unit of a television, a notebook computer, a monitor, a billboard, or an Internet of things (IoT) device. For another example, the display device 10 may be applied to wearable devices, such as smart watches, watch phones, glasses-type displays, and head mounted displays.

The display device 10 may have a planar shape similar to a quadrangle. For example, the display device 10 may have a planar shape similar to a quadrangle having short sides in an X-axis direction (e.g., a first direction) and long sides in a Y-axis direction (e.g., a second direction). Each corner where a short side extending in the X-axis direction meets a long side extending in the Y-axis direction may be rounded with a set curvature (e.g., a preset or predetermined curvature) or may be right-angled. The planar shape of the display device 10 is not limited to the quadrangular shape but may also be similar to other polygonal shapes, a circular shape, or an oval shape.

The display device 10 may include a display panel 100, a display driver 200, a circuit board 300, and a touch driver 400.

The display panel 100 may include a main area MA and a sub-area SBA.

The main area MA may include a display area DA including pixels that display an image and a non-display area NDA disposed around the display area DA. The display area DA may emit light from a plurality of emission areas or a plurality of opening areas. For example, the display panel 100 may include pixel circuits including switching elements, a pixel defining layer defining the emission areas or the opening areas, and self-light emitting elements.

For example, each of the self-light emitting elements may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode.

The non-display area NDA may be an area outside the display area DA. The non-display area NDA may be defined as an edge area of the main area MA of the display panel 100. The non-display area NDA may include a gate driver which supplies gate signals to gate lines and fan-out lines which connect the display driver 200 and the display area DA.

The sub-area SBA may extend from a side of the main area MA. The sub-area SBA may include a flexible material that can be bent, folded, rolled, etc. For example, when the sub-area SBA is bent, it may be overlapped by the main area MA in a thickness direction (Z-axis direction). The sub-area SBA may include the display driver 200 and a pad unit connected to the circuit board 300. Optionally, the sub-area SBA may be omitted, and the display driver 200 and the pad unit may be disposed in the non-display area NDA.

The display driver 200 may output signals and voltages for driving the display panel 100. The display driver 200 may supply data voltages to data lines. The display driver 200 may supply a power supply voltage to a power line and supply a gate control signal to the gate driver. The display driver 200 may be formed as an integrated circuit and mounted on the display panel 100 by a chip on glass (COG) method, a chip on plastic (COP) method, or an ultrasonic bonding method. For example, the display driver 200 may be disposed in the sub-area SBA and may be overlapped by the main area MA in the thickness direction (Z-axis direction) by the bending of the sub-area SBA. For another example, the display driver 200 may be mounted on the circuit board 300.

The circuit board 300 may be attached onto the pad unit of the display panel 100 using an anisotropic conductive film. Lead lines of the circuit board 300 may be electrically connected to the pad unit of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and sense a change in capacitance between the touch electrodes. For example, the touch driving signal may be a pulse signal having a set frequency (e.g., a preset or predetermined frequency). The touch driver 400 may determine whether an input has been made based on a change in capacitance between the touch electrodes and calculate coordinates of the input. The touch driver 400 may be formed as an integrated circuit.

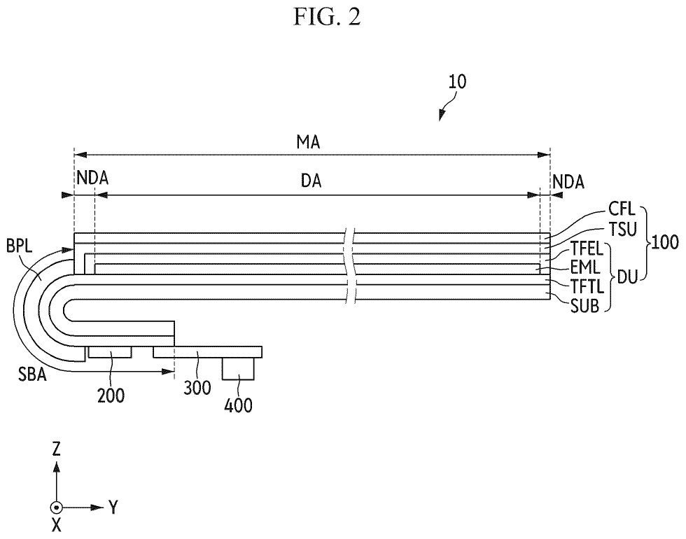

FIG. 2 is a cross-sectional view of the display device according to some embodiments of the present disclosure.

Referring to FIG. 2, the display panel 100 may include a display unit DU, a touch sensing unit TSU, and a color filter layer CFL. The display unit DU may include a substrate SUB, a transistor layer TFTL, a light emitting element layer EML, and an encapsulation layer TFEL.

The substrate SUB may be a base substrate or a base member. The substrate SUB may be a flexible substrate that can be bent, folded, rolled, etc. For example, the substrate SUB may include polymer resin such as polyimide (PI), but the present disclosure is not limited thereto. For another example, the substrate SUB may include a glass material or a metal material.

The transistor layer TFTL may be disposed on the substrate SUB. The transistor layer TFTL may include a plurality of transistors constituting pixel circuits of pixels. The transistor layer TFTL may further include gate lines, data lines, power lines, gate control lines, fan-out lines connecting the display driver 200 and the data lines, and lead lines connecting the display driver 200 and the pad unit. Each of the transistors may include a semiconductor region, a source electrode, a drain electrode, and a gate electrode. For example, when the gate driver is formed on a side of the non-display area NDA of the display panel 100, it may include transistors.

The transistor layer TFTL may be disposed in the display area DA, the non-display area NDA, and the sub-area SBA. The transistors of the pixels, the gate lines, the data lines, and the power lines of the transistor layer TFTL may be disposed in the display area DA. The gate control lines and the fan-out lines of the transistor layer TFTL may be disposed in the non-display area NDA. The lead lines of the transistor layer TFTL may be disposed in the sub-area SBA.

The light emitting element layer EML may be disposed on the transistor layer TFTL. The light emitting element layer EML may include a plurality of light emitting elements, each including an anode electrode, a light emitting layer, and a cathode electrode sequentially stacked to emit light, and a pixel defining layer defining the pixels. The light emitting elements of the light emitting element layer EML may be disposed in the display area DA.

For example, the light emitting layer may be an organic light emitting layer including an organic material. The light emitting layer may include an anode electrode, a hole transporting layer, an organic light emitting layer, an electron transporting layer, and a cathode electrode. When the anode electrode receives a driving voltage and the cathode electrode supplies a set voltage (e.g., a preset or predetermined voltage) to a transistor of the transistor layer TFTL, holes may move to the organic light emitting layer through the hole transporting layer, and electrons may move to the organic light emitting layer through the electron transporting layer.

For another example, each of the light emitting elements may include a quantum dot light emitting diode including a quantum dot light emitting layer, an inorganic light emitting diode including an inorganic semiconductor, or a micro light emitting diode.

The encapsulation layer TFEL may cover upper and side surfaces of the light emitting element layer EML and may protect the light emitting element layer EML. The encapsulation layer TFEL may include at least one inorganic layer and at least one organic layer to encapsulate the light emitting element layer EML.

The touch sensing unit TSU may be disposed on the encapsulation layer TFEL. The touch sensing unit TSU may include a plurality of touch electrodes for sensing a user's touch in a capacitive manner and touch lines connecting the touch electrodes and the touch driver 400. For example, the touch sensing unit TSU may sense a user's touch in a mutual capacitance manner or a self-capacitance manner.

For another example, the touch sensing unit TSU may be disposed on a separate substrate disposed on the display unit DU. For example, the substrate supporting the touch sensing unit TSU may be an encapsulation substrate that encapsulates the display unit DU.

The touch electrodes of the touch sensing unit TSU may be disposed in a touch sensor area overlapping the display area DA. The touch lines of the touch sensing unit TSU may be disposed in a touch peripheral area overlapping (e.g., overlapping with) the non-display area NDA.

The color filter layer CFL may be disposed on the touch sensing unit TSU. The color filter layer CFL may include a plurality of color filters corresponding to a plurality of emission areas, respectively. Each of the color filters may selectively transmit light of a specific wavelength and block or absorb light of other wavelengths. The color filter layer CFL may absorb a part of light coming from the outside of the display device 10, thereby reducing reflected light caused by the external light. Therefore, the color filter layer CFL can prevent color distortion caused by reflection of external light.

Because the color filter layer CFL may be directly disposed on the touch sensing unit TSU, the display device 10 may not require a separate substrate for the color filter layer CFL. Therefore, a thickness of the display device 10 can be relatively reduced.

The sub-area SBA of the display panel 100 may extend from a side of the main area MA. The sub-area SBA may include a flexible material that can be bent, folded, rolled, etc. For example, when the sub-area SBA is bent, it may be overlapped by the main area MA in the thickness direction (Z-axis direction). The sub-area SBA may include the display driver 200 and the pad unit electrically connected to the circuit board 300.

The display device 10 may include a bending protection layer BPL which protects the sub-area SBA. The bending protection layer BPL may be disposed on the transistor layer TFTL of the bent sub-area SBA. The bending protection layer BPL may protect the transistor layer TFTL of the bent sub-area SBA and minimize (reduce) tensile stress of the sub-area SBA.

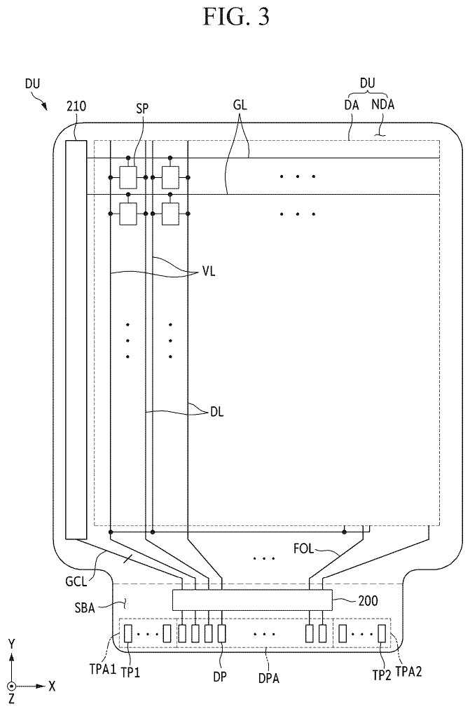

FIG. 3 is a plan view of a display unit of the display device according to some embodiments of the present disclosure.

Referring to FIG. 3, the display unit DU may include the display area DA and the non-display area NDA.

The display area DA is an area for displaying an image and may be defined as a central area of the display panel 100. The display area DA may include a plurality of pixels SP, a plurality of gate lines GL, a plurality of data lines DL, and a plurality of power lines VL. Each of the pixels SP may be defined as a minimum unit that outputs light.

The gate lines GL may supply gate signals received from a gate driver 210 to the pixels SP. The gate lines GL may extend in the X-axis direction and may be spaced apart from each other in the Y-axis direction intersecting the X-axis direction.

The data lines DL may supply data voltages received from the display driver 200 to the pixels SP. The data lines DL may extend in the Y-axis direction and may be spaced apart from each other in the X-axis direction.

The power lines VL may supply a power supply voltage received from the display driver 200 to the pixels SP. For example, the power supply voltage may be at least one of a driving voltage, an initialization voltage, a reference voltage, a bias voltage, and a low potential voltage. The power lines VL may extend in the Y-axis direction and may be spaced apart from each other in the X-axis direction.

The non-display area NDA may surround the display area DA. The non-display area NDA may include the gate driver 210, fan-out lines FOL, and gate control lines GCL. The gate driver 210 may generate a plurality of gate signals based on a gate control signal and sequentially supply the gate signals to the gate lines GL according to a set order.

The fan-out lines FOL may extend from the display driver 200 to the display area DA. The fan-out lines FOL may supply data voltages received from the display driver 200 to the data lines DL.

The gate control lines GCL may extend from the display driver 200 to the gate driver 210. The gate control lines GCL may supply a gate control signal received from the display driver 200 to the gate driver 210.

The sub-area SBA may include the display driver 200, a display pad area DPA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be supplied to the pixels SP and may determine luminances of the pixels SP. The display driver 200 may supply a gate control signal to the gate driver 210 through the gate control lines GCL.

The display pad area DPA, the first touch pad area TPA1, and the second touch pad area TPA2 may be disposed at an edge of the sub-area SBA. The display pad area DPA, the first touch pad area TPA1, and the second touch pad area TPA2 may be electrically connected to the circuit board 300 using a low-resistance, high-reliability material, such as an anisotropic conductive film or self-assembly anisotropic conductive paste (SAP).

The display pad area DPA may include a plurality of display pad units DP. The display pad units DP may be electrically connected to a graphics system through the circuit board 300. The display pad units DP may be connected to the circuit board 300 to receive digital video data and may supply the digital video data to the display driver 200.

The first touch pad area TPA1 may be disposed on a side of the display pad area DPA and may include a plurality of first touch pad units TP1. The first touch pad units TP1 may be electrically connected to the touch driver 400 disposed on the circuit board 300. The first touch pad units TP1 may supply touch driving signals to a plurality of driving electrodes through a plurality of driving lines.

The second touch pad area TPA2 may be disposed on the other side of the display pad area DPA and may include a plurality of second touch pad units TP2. The second touch pad units TP2 may be electrically connected to the touch driver 400 disposed on the circuit board 300. The touch driver 400 may receive touch sensing signals through a plurality of sensing lines connected to the second touch pad units TP2 and sense a change in mutual capacitance between the driving electrodes and sensing electrodes.

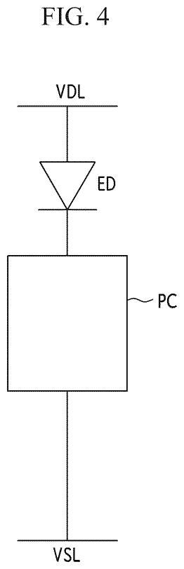

FIG. 4 is a schematic drawing of a pixel of the display device according to some embodiments of the present disclosure.

Referring to FIG. 4, a pixel SP may include a light emitting element ED and a pixel circuit PC driving a light emitting element ED. For example, the pixel SP may have an inverted pixel structure. By having an inverted pixel structure, the display device 10 may reduce deterioration of the light emitting element ED and minimize or substantially reduce afterimages of a product.

The light emitting element ED may receive the driving current and emit light. The amount of light emitted from the light emitting element ED or the luminance of the light emitting element ED may be proportional to the magnitude of the driving current. The light emitting element ED may include a first electrode, a second electrode, and a light emitting layer disposed between the first electrode and the second electrode. The first electrode of the light emitting element ED may be electrically connected to a driving voltage line VDL and receive a driving voltage from the driving voltage line VDL. The second electrode of the light emitting element ED may be electrically connected to the pixel circuit PC. For example, the first electrode of the light emitting element ED may be an anode electrode, and the second electrode thereof may be a cathode electrode. It is, however, to be understood that the present disclosure is not limited thereto.

The pixel circuit PC may be electrically connected between the light emitting element ED and a low potential voltage line VSL. The pixel circuit PC may include at least one transistor and at least one capacitor. For example, the at least one transistor may include an oxide-based semiconductor region. The transistor may have a coplanar structure in which a gate electrode is disposed at a top portion of an oxide-based semiconductor region. The transistor including the oxide-based semiconductor region may have desirable leakage current characteristics and may be driven at low frequencies, thereby reducing power consumption. Accordingly, as the display device 10 includes a transistor having desirable leakage current characteristics, leakage current may be prevented from flowing in the pixel (or the leakage current flowing in the pixel may be substantially reduced) and stably maintain the voltage in the pixel.

For another example, the at least one transistor may include a silicon-based semiconductor region. The transistor may include a semiconductor region formed of a low temperature polycrystalline silicon (LTPS). The semiconductor region formed of a low temperature polycrystalline silicon may have high electron mobility and desirable turn-on characteristics. Accordingly, as the display device 10 may include a transistor with desirable turn-on characteristics, the plurality of pixels SP may be stably and effectively driven.

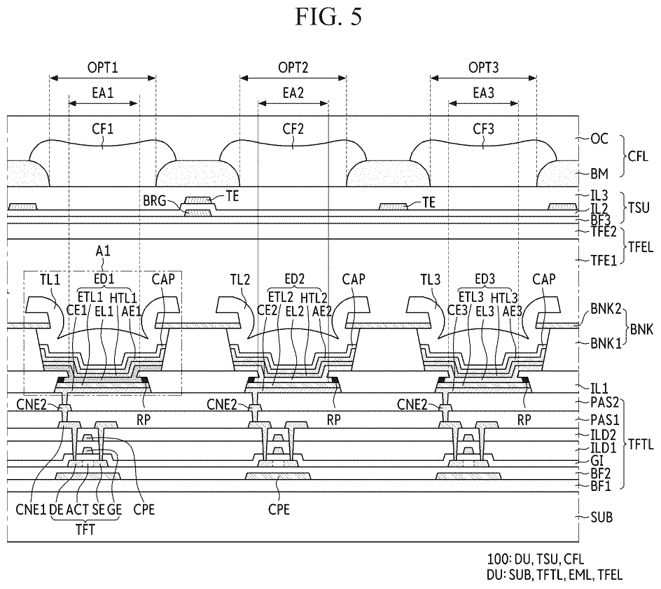

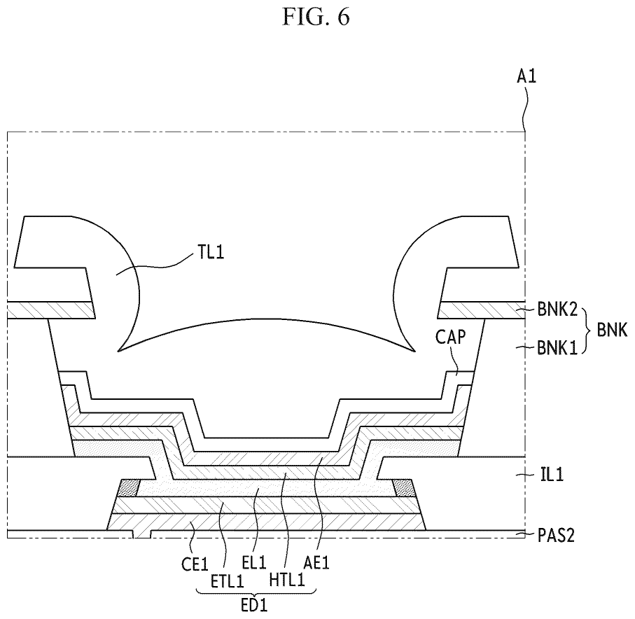

FIG. 5 is a cross-sectional view illustrating pixels of the display device according to some embodiments of the present disclosure, and FIG. 6 is an enlarged view of area A1 of FIG. 5 according to some embodiments of the present disclosure.

Referring to FIGS. 5 and 6, the display panel 100 may include a display unit DU (see, e.g., FIG. 3), a touch sensing unit TSU, and a color filter layer CFL. The display unit DU may include a substrate SUB, a transistor layer TFTL, a light emitting element layer EML, and an encapsulation layer TFEL.

1 The substrate SUB may be a base substrate or a base member. The substrate SUB may be a flexible substrate which can be bent, folded or rolled. For example, the substrate SUB may include a polymer resin such as polyimide (PI), but is not limited thereto. For another example, the substrate SUB may include a glass material or a metal material.

The transistor layer TFTL may include a first buffer layer BF1, a second buffer layer BF2, a transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic layer that can prevent or substantially reduce penetration of air or moisture. For example, the first buffer layer BF1 may include a plurality of inorganic layers that are alternately stacked.

The second buffer layer BF2 may be disposed on the first buffer layer BF1. The second buffer layer BF2 may include an inorganic layer that can prevent or substantially reduce penetration of air or moisture. For example, the second buffer layer BF2 may include a plurality of inorganic layers that are stacked alternately.

The transistors TFT may be disposed on the second buffer layer BF2 and may constitute pixel circuits of pixels. For example, each of the transistors TFT may be a driving transistor or a switching transistor of a pixel circuit. Each of the transistors TFT may include a semiconductor region ACT, a source electrode SE, a drain electrode DE, and a gate electrode GE.

The semiconductor region ACT, the source electrode SE, and the drain electrode DE may be disposed on (e.g., disposed at) the second buffer layer BF2. The semiconductor region ACT, the source electrode SE, and the drain electrode DE may overlap with a light blocking layer in the thickness direction. The semiconductor region ACT may be overlapped by the gate electrode GE in the thickness direction and may be insulated from the gate electrode GE by the gate insulating layer GI. The source electrode SE and the drain electrode DE may be formed by making the material of the semiconductor region ACT conductive.

The gate electrode GE may be disposed on the gate insulating layer GI. The gate electrode GE may overlap with the semiconductor region ACT with the gate insulating layer GI interposed between them.

The gate insulating layer GI may be disposed on the semiconductor regions ACT, the source electrodes SE, the drain electrodes DE, and the second buffer layer BF2. The gate insulating layer GI may insulate the semiconductor regions ACT from the gate electrodes GE.

The first interlayer insulating layer ILD1 may be disposed on the gate electrodes GE and the gate insulating layer GI. The first interlayer insulating layer ILD1 may insulate the gate electrodes GE from the capacitor electrodes CPE.

The capacitor electrodes CPE may be disposed on the first interlayer insulating layer ILD1. The capacitor electrodes CPE may overlap with the gate electrodes GE in the thickness direction. The capacitor electrodes CPE and the gate electrodes GE may form capacitances.

The second interlayer insulating layer ILD2 may be disposed on the capacitor electrodes CPE and the first interlayer insulating layer ILD1. The second interlayer insulating layer ILD2 may insulate the capacitor electrodes CPE from the first connection electrodes CNE1.

The first connection electrodes CNE1 may be disposed on the second interlayer insulating layer ILD2. The first connection electrodes CNE1 may electrically connect the drain electrodes DE of the transistors TFT to the second connection electrodes CNE2. The first connection electrodes CNE1 may be inserted into contact holes provided in the second interlayer insulating layer ILD2, the first interlayer insulating layer ILD1 and the gate insulating layer GI to contact the drain electrodes DE of the transistors TFT.

The first passivation layer PAS1 may be disposed on the first connection electrodes CNE1 and the second interlayer insulating layer ILD2. The first passivation layer PAS1 may protect the transistors TFT. The first passivation layer PAS1 may insulate the first connection electrodes CNE1 and the second connection electrodes CNE2.

The second connection electrodes CNE2 may be disposed on the first passivation layer PAS1. A second connection electrode CNE2 may electrically connect a first connection electrode CNE1 to a first cathode electrode CE1 of a first light emitting element ED1. The second connection electrodes CNE2 may be inserted into contact holes provided in the first passivation layer PAS1 to contact the first connection electrodes CNE1.

The second passivation layer PAS2 may be disposed on the second connection electrodes CNE2 and the first passivation layer PAS1. The second passivation layer PAS2 may insulate the second connection electrodes CNE2 and the first cathode electrode CE1.

The light emitting element layer EML may be disposed on the transistor layer TFTL. The light emitting element layer EML may include first to third light emitting elements ED1 to ED3, residual patterns RP, a first insulating layer IL1, a capping layer CAP, a bank BNK, and first to third inorganic layers TL1 through TL3.

The display device 10 may include a plurality of pixels arranged along a plurality of rows and a plurality of columns in the display area DA. The pixels may respectively include first through third emission areas EA1 through EA3 defined by the bank BNK or the pixel defining layer and may emit light having a set (e.g., preset or predetermined) peak wavelength through first through third emission areas EA1 through EA3. Each of the first through third emission areas EA1 through EA3 may be an area where light generated by the first through third light emitting elements ED1 through ED3 is emitted to the outside of the display device 10.

Each of the first through third emission areas EA1 through EA3 may emit light having a set (e.g., preset or predetermined) peak wavelength to the outside of the display device 10. The first emission area EA1 may emit light of a first color, the second emission area EA2 may emit light of a second color, and the third emission area EA3 may emit light of a third color. For example, the light of the first color may be red light having a peak wavelength of about 610 nm to about 650 nm, the light of the second color may be green light having a peak wavelength of about 510 nm to about 550 nm, and the light of the third color may be blue light having a peak wavelength of about 440 nm to about 480 nm. However, the present disclosure is not limited thereto.

For example, the area of the third emission area EA3 may be larger than the area of the first emission area EA1, and the area of the first emission area EA1 may be larger than the area of the second emission area EA2. However, the present disclosure is not limited thereto. For another example, the area of the first emission area EA1, the area of the second emission area EA2, and the area of the third emission area EA3 may be substantially the same.

The first light emitting element ED1 may be disposed on the transistor layer TFTL in the first emission area EA1. The first light emitting element ED1 may include a first anode electrode AE1, a first hole transporting layer HTL1, a first light emitting layer EL1, a first electron transporting layer ETL1, and a first cathode electrode CE1. The second light emitting element ED2 may be disposed on the transistor layer TFTL in the second emission area EA2. The second light emitting element ED2 may include a second anode electrode AE2, a second hole transporting layer HTL2, a second light emitting layer EL2, a second electron transporting layer ETL2, and a second cathode electrode CE2. The third light emitting element ED3 may be disposed on the transistor layer TFTL in the third emission area EA3. The third light emitting element ED3 may include a third anode electrode AE3, a third hole transporting layer HTL3, a third light emitting layer EL3, a third electron transporting layer ETL3, and a third cathode electrode CE3.

The first through third cathode electrodes CE1 through CE3 may be disposed on the second passivation layer PAS2. Each of the first through third cathode electrodes CE1 through CE3 may be electrically connected to the drain electrode DE of a transistor TFT through the first and second connection electrodes CNE1 and CNE2. The first through third cathode electrodes CE1 through CE3 may be insulated from each other by the first insulating layer IL1. For example, the first through third cathode electrodes CE1 through CE3 may include at least one of silver (Ag), titanium (Ti), copper (Cu), aluminum (Al), nickel (Ni), and lanthanum (La). The first through third cathode electrodes CE1 through CE3 may be reflective electrodes including a material having high reflectivity. The first through third cathode electrodes CE1 through CE3 may have a thickness of about 600 angstroms (Å) or more, but the present disclosure is not limited thereto.

The first electron transporting layer ETL1 may be disposed on the first cathode electrode CE1 in the first emission area EA1. The second electron transporting layer ETL2 may be disposed on the second cathode electrode CE2 in the second emission area EA2. The third electron transporting layer ETL3 may be disposed on the third cathode electrode CE3 in the third emission area EA3. For example, the first electron transporting layer ETL1 may supply an electron to the first light emitting layer EL1 during the process in which the first light emitting element ED1 emits light. For example, the first through third electron transporting layer ETL1 through ETL3 may include ytterbium (Yb) or zinc (Zn), but the present disclosure is not limited thereto.

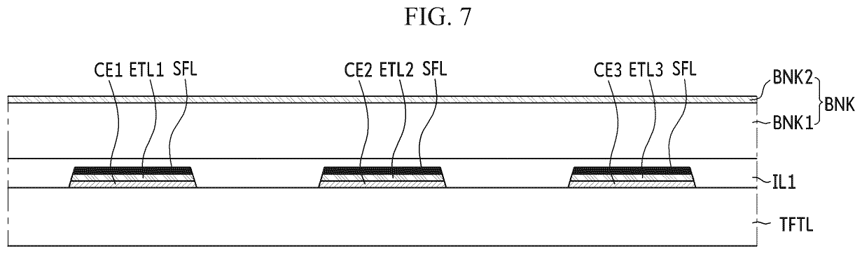

Residual patterns RP may be disposed on edges of each of the first through third electron transporting layer ETL1 through ETL3. The first insulating layer IL1 may not directly contact an upper surface of each of the first through third electron transporting layer ETL1 through ETL3 due to the residual patterns RP. The residual patterns RP may be formed as a result of removing a sacrificial layer SFL (see, e.g., FIG. 7) on each of the first through third electron transporting layer ETL1 through ETL3 in a process of manufacturing the display device 10.

The first insulating layer IL1 may be disposed on the second passivation layer PAS2 and the residual patterns RP. The first insulating layer IL1 may be disposed on the edges of the first through electron transporting layer ETL1 through ETL3 and the residual patterns RP and may partially expose the upper surfaces of the first through third electron transporting layer ETL1 through ETL3. For example, the first insulating layer IL1 may expose the first electron transporting layer ETL1 in the first emission area EA1, and the first light emitting layer EL1 may be directly disposed on the first electron transporting layer ETL1. The first insulating layer IL1 may include an inorganic insulating material. The first insulating layer IL1 may include, but is not limited to, at least one of a silicon nitride layer, a silicon oxynitride layer, a silicon oxide layer, a titanium oxide layer, an aluminum oxide layer, and an amorphous silicon layer.

The first through third light emitting layers EL1 through EL3 may be organic light emitting layers made of an organic material and may be formed on the first through third electron transporting layer ETL1 through ETL3 through a deposition process. For example, an organic material may be deposited in a direction inclined from an upper surface of the substrate SUB in a deposition process of the first through third light emitting layers EL1 through EL3.

The first light emitting layer EL1 may be disposed on the first electron transporting layer ETL1 in the first emission area EA1. A portion of the first light emitting layer EL1 may fill a space surrounded by the first electron transporting layer ETL1, the residual patterns RP and the first insulating layer IL1, and another portion of the first light emitting layer EL1 may cover upper surfaces of edges and side surfaces of the first insulating layer IL1. The second light emitting layer EL2 may be disposed on the second electron transporting layer ETL2 in the second emission area EA2. A portion of the second light emitting layer EL2 may fill a space surrounded by the second electron transporting layer ETL2, the residual patterns RP, and the first insulating layer IL1, and another portion of the second light emitting layer EL2 may cover the upper surfaces of the edges and the side surfaces of the first insulating layer IL1. The third light emitting layer EL3 may be disposed on the third electron transporting layer ETL3 in the third emission area EA3. A portion of the third light emitting layer EL3 may fill a space surrounded by the third electron transporting layer ETL3, the residual patterns RP and the first insulating layer IL1, and another portion of the third light emitting layer EL3 may cover the upper surfaces of the edges and the side surfaces of the first insulating layer IL1.

The first hole transporting layer HTL1 may be disposed on the first light emitting layer EL1 in the first emission area EA1. The second hole transporting layer HTL2 may be disposed on the second light emitting layer EL2 in the second emission area EA2. The third hole transporting layer HTL3 may be disposed on the third light emitting layer EL3 in the third emission area EA3. For example, the first hole transporting layer HTL1 may supply a hole to the first light emitting layer EL1 during the process in which the first light emitting element ED1 emits light. For example, the first through third hole transporting layer HTL1 through HTL3 may include nickel (Ni), but the present disclosure is not limited thereto.

The first anode electrode AE1 may be disposed on the first hole transporting layer HTL1, the second anode electrode AE2 may be disposed on the second hole transporting layer HTL2, and the third anode electrode AE3 may be disposed on the third light emitting layer EL3. The first through third anode electrodes AE1 through AE3 may have translucency or transparency (e.g., may be transparent). The thickness of each of the first through third anode electrodes AE1 through AE3 may be about tens to about hundreds of angstroms (Å). For example, when the first through third anode electrodes AE1 through AE3 have translucency, the first through third anode electrodes AE1 through AE3 may include Ag, Mg, Cu, Al, Pt, Pd, Au, Ni, Nd, Ir, Cr, Li, Ca, LiF/Ca, LiF/Al, Mo, Ti, or a compound or mixture thereof. For another example, the first through third anode electrodes AE1 through AE3 may include a transparent conductive oxide and have transparency. When the first through third anode electrodes AE1 through AE3 have transparency, the first through third anode electrodes AE1 through AE3 may include tungsten oxide (WxOx), titanium oxide (TiO2), indium tin oxide (ITO), indium zinc oxide (IZO), zinc oxide (ZnO), indium tin zinc oxide (ITZO), or magnesium oxide (MgO). The first through third anode electrodes AE1 through AE3 may be in contact with the side surfaces of a first bank BNK1 to be electrically connected. The first through third anode electrodes AE1 through AE3 may be electrically connected to the driving voltage line VDL of FIG. 4 to receive a driving voltage or a high potential voltage.

The first anode electrode AE1 may receive a driving voltage, and the first cathode electrode CE1 may supply a set voltage (e.g., a preset or predetermined voltage) to the transistor TFT of the pixel SP. Because a potential difference is formed between the first anode electrode AE1 and the first cathode electrode CE1, holes may move to the first light emitting layer EL1 through the first hole transporting layer HTL1, and electrons may move to the first light emitting layer EL1 through the first electron transporting layer ETL1. Accordingly, the first light emitting layer EL1 may emit light.

The capping layers CAP may be disposed on the first through third anode electrodes AE1 through AE3 in the first through third emission areas EA1 through EA3. The capping layers CAP may include an inorganic insulating material and may cover the first through third light emitting elements ED1 through ED3. The capping layers CAP may prevent the first through third light emitting elements ED1 through ED3 from being damaged by external air or substantially reduce the damage. For example, the capping layers CAP may include, but are not limited to, at least one of a silicon nitride layer, a silicon oxynitride layer, a silicon oxide layer, a titanium oxide layer, an aluminum oxide layer, and an amorphous silicon layer.

The bank BNK may be disposed on the first insulating layer IL1 to define the first through third emission areas EA1 through EA3. The bank BNK may surround the first through third emission areas EA1 through EA3 in a plan view. The bank BNK may include first and second banks BNK1 and BNK2.

The first bank BNK1 may be disposed on the first insulating layer IL1, and the second bank BNK2 may be disposed on the first bank BNK1. Side surfaces of the first bank BNK1 may be recessed inward from side surfaces of the second bank BNK2. Because the side surfaces of the second bank BNK2 protrude from the side surfaces of the first bank BNK1 toward the first emission area EA1, the second bank BNK2 may include protruding tips. Accordingly, an undercut structure may be formed under each tip of the second bank BNK2. A thickness of the first bank BNK1 may be greater than a thickness of the second bank BNK2.

The first and second banks BNK1 and BNK2 may include different metal materials. An etching rate of the first bank BNK1 and an etching rate of the second bank BNK2 may be different from each other. For example, the etching rate of the first bank BNK1 may be higher than that of the second bank BNK2 in a wet etching process, and the first bank BNK1 may be etched more than the second bank BNK2 in the process of forming the first through third emission areas EA1 through EA3. Therefore, the side shape of the first and second banks BNK1 and BNK2 may be determined by a difference in etching rate between the first and second banks BNK1 and BNK2. The first bank BNK1 may include a metal material having high electrical conductivity, and the second bank BNK2 may include a material having low reflectivity. For example, the first bank BNK1 may include aluminum (Al), and the second bank BNK2 may include titanium (Ti). However, the present disclosure is not limited thereto.

1 The bank BNK may include openings that form the first through third emission areas EA1 through EA3 and may be overlapped by a light blocking member BM of the color filter layer CFL. The first bank BNK1 may electrically connect the first through third anode electrodes AE1 through-AE3 spaced apart from each other. The second bank BNK2 may include a material having low reflectivity to reduce reflection of external light.

The bank BNK may form the first through third emission areas EA1 through EA3 through a mask process, and the first through third light emitting layers EL1 through EL3 may be formed in the first through third emission areas EA1 through EA3, respectively. When a mask process is performed, a structure for supporting a mask may be required, and an excessively wide non-display area NDA may be required to control distribution of the mask process. Therefore, if the mask process is minimized or substantially reduced, a structure for supporting a mask can be omitted, and the area of the non-display area NDA for distribution control can be minimized or substantially reduced.

The first through third light emitting elements ED1 through ED3 may be formed through deposition and etching processes rather than a mask process. Because the first and second banks BNK1 and BNK2 include different metal materials, each inner wall of the bank BNK may have a tip structure. In the display device 10, different layers may be individually formed in the first through third emission areas EA1 through EA3 through a deposition process. For example, the first light emitting layer EL1 may be deposited in the first emission area EA1 by the tips formed on the inner walls of the bank BNK in the process of depositing an organic material without using a mask, and the organic material not disposed in the first emission area EA1 may be removed through an etching process.

An organic material for forming the first light emitting layer EL1 may be deposited on the entire surface of the display device 10, and the organic material of the first light emitting layer EL1 deposited in the second and third emission areas EA2 and EA3 may be removed. An organic material for forming the second light emitting layer EL2 may be deposited on the entire surface of the display device 10, and the organic material of the second light emitting layer EL2 deposited in the first and third emission areas EA1 and EA3 may be removed. An organic material for forming the third light emitting layer EL3 may be deposited on the entire surface of the display device 10, and the organic material of the third light emitting layer EL3 deposited in the first and second emission areas EA1 and EA2 may be removed. Therefore, in the display device 10, different organic materials can be formed in the first through third emission areas EA1 through EA3 through deposition and etching processes without using a mask process. The display device 10 can reduce manufacturing costs by omitting unnecessary processes and can minimize or substantially reduce the area of the non-display area NDA.

The first inorganic layer TL1 may be disposed on the capping layer CAP of the first emission area EA1 to cover an upper surface of the capping layer CAP. The first inorganic layer TL1 may cover the side surfaces of the first bank BNK1 and lower and side surfaces of the tips of the second bank BNK2. The first inorganic layer TL1 may have a cavity structure spaced apart from the upper surface of the second bank BNK2. The first inorganic layer TL1 may include an inorganic material to prevent oxygen or moisture from penetrating into the first light emitting element ED1 or to reduce the likelihood of that occurring. The first inorganic layer TL1 may be an inorganic encapsulation layer. For example, the first inorganic layer TL1 may include, but is not limited to, at least one of a silicon nitride layer, a silicon oxynitride layer, a silicon oxide layer, a titanium oxide layer, an aluminum oxide layer, and an amorphous silicon layer.

The second inorganic layer TL2 may be disposed on the capping layer CAP of the second emission area EA2 to cover an upper surface of the capping layer CAP. The second inorganic layer TL2 may cover the side surfaces of the first bank BNK1, and lower and side surfaces of the tips of the second bank BNK2. The second inorganic layer TL2 may have a cavity structure spaced apart from the upper surface of the second bank BNK2. The second inorganic layer TL2 may include an inorganic material to prevent oxygen or moisture from penetrating into the second light emitting element ED2 or to reduce the likelihood of that occurring. The second inorganic layer TL2 may be an inorganic encapsulation layer. For example, the second inorganic layer TL2 may be made of any of the materials exemplified in the description of the first inorganic layer TL1.

The third inorganic layer TL3 may be disposed on the capping layer CAP of the third emission area EA3 to cover an upper surface of the capping layer CAP. The third inorganic layer TL3 may cover the side surfaces of the first bank BNK1, and lower and side surfaces of the tips of the second bank BNK2. The third inorganic layer TL3 may have a cavity structure spaced apart from the upper surface of the second bank BNK2. The third inorganic layer TL3 may include an inorganic material to prevent oxygen or moisture from penetrating into the third light emitting element ED3 or to reduce the likelihood of that occurring. The third inorganic layer TL3 may be an inorganic encapsulation layer. For example, the third inorganic layer TL3 may be made of any of the materials exemplified in the description of the first inorganic layer TL1.

The encapsulation layer TFEL may be disposed on the first through third inorganic layers TL1 through TL3 to cover the light emitting element layer EML. The encapsulation layer TFEL may include first and second encapsulation layers TFE1 and TFE2.

The first encapsulation layer TFE1 may be disposed on the first through third inorganic layers TL1 through TL3. The first encapsulation layer TFE1 may cover the second bank BNK2 exposed between the first through third inorganic layers TL1 through TL3. The first encapsulation layer TFE1 may be disposed on the first through third inorganic layers TL1 through TL3 to planarize an upper end of the light emitting element layer EML. The first encapsulation layer TFE1 may include an organic material to protect the light emitting element layer EML from foreign substances, such as dust. For example, the first encapsulation layer TFE1 may include an organic layer such as acryl resin, epoxy resin, phenolic resin, polyamide resin, or polyimide resin. The first encapsulation layer TFE1 may be formed by curing a monomer or applying a polymer.

The second encapsulation layer TFE2 may be disposed on the first encapsulation layer TFE1. The second encapsulation layer TFE2 may include an inorganic material to prevent oxygen or moisture from penetrating into the light emitting element layer EML or to reduce the likelihood of that occurring. For example, the second encapsulation layer TFE2 may include, but is not limited to, at least one of a silicon nitride layer, a silicon oxynitride layer, a silicon oxide layer, a titanium oxide layer, an aluminum oxide layer, and an amorphous silicon layer.

The touch sensing unit TSU may be disposed on the encapsulation layer TFEL. The touch sensing unit TSU may include a third buffer layer BF3, a bridge electrode BRG, a second insulating layer IL2, touch electrodes TE, and a third insulating layer IL3.

The third buffer layer BF3 may be disposed on the encapsulation layer TFEL. The third buffer layer BF3 may have insulating and optical functions. The third buffer layer BF3 may include at least one inorganic layer. In some embodiments, the third buffer layer BF3 may be omitted.

The bridge electrode BRG may be disposed on the third buffer layer BF3. The bridge electrode BRG may be disposed on a different layer from the touch electrodes TE and may electrically connect adjacent touch electrodes TE.

The second insulating layer IL2 may be disposed on the bridge electrode BRG and the third buffer layer BF3. The second insulating layer IL2 may have insulating and optical functions. For example, the second insulating layer IL2 may include, but is not limited to, at least one of a silicon nitride layer, a silicon oxynitride layer, a silicon oxide layer, a titanium oxide layer, an aluminum oxide layer, and an amorphous silicon layer.

The touch electrodes TE may be disposed on the second insulating layer IL2. The touch electrodes TE may include a driving electrode and a sensing electrode and may sense a change in mutual capacitance between the driving electrode and the sensing electrode. The touch electrodes TE may not overlap the first through third emission areas EA1 through EA3. Each of the touch electrodes TE may be a single layer of molybdenum (Mo), titanium (Ti), copper (Cu), aluminum (Al), or indium tin oxide (ITO) or may be a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

The third insulating layer IL3 may be disposed on the touch electrodes TE and the second insulating layer IL2. The third insulating layer IL3 may have insulating and optical functions. The third insulating layer IL3 may be made of any of the materials exemplified in the description of the second insulating layer IL2.

The color filter layer CFL may be disposed on the touch sensing unit TSU. The color filter layer CFL may include the light blocking member BM, first through third color filters CF1 through CF3, and a planarization layer OC.

The light blocking member BM may be disposed on the third insulating layer IL3 to surround first through third optical areas OPT1 through OPT3. The light blocking member BM may overlap the touch electrodes TE. The light blocking member BM may include a light absorbing material to prevent reflection of light. For example, the light blocking member BM may include an inorganic black pigment, an organic black pigment, or an organic blue pigment. The inorganic black pigment may be a metal oxide such as carbon black or titanium black, the organic black pigment may include at least one of lactam black, perylene black, and aniline black, and the organic blue pigment may be CI pigment blue. However, the present disclosure is not limited thereto. The light blocking member BM may prevent color mixing by preventing intrusion of visible light between the first through third emission areas EA1 through EA3, thereby improving a color gamut of the display device 10.

The first through third color filters CF1 through CF3 may be disposed on the third insulating layer IL3 to correspond to the first through third emission areas EA1 through EA3, respectively.

The first color filter CF1 may be disposed on the third insulating layer IL3 in the first emission area EA1. The first color filter CF1 may be surrounded by the light blocking member BM in a plan view. Edges of the first color filter CF1 may partially cover an upper surface of the light blocking member BM, but the present disclosure is not limited thereto. The first color filter CF1 may selectively transmit light of the first color (e.g., red light) and block or absorb light of the second color (e.g., green light) and light of the third color (e.g., blue light). For example, the first color filter CF1 may be a red color filter and may include a red colorant.

The second color filter CF2 may be disposed on the third insulating layer IL3 in the second emission area EA2. The second color filter CF2 may be surrounded by the light blocking member BM in a plan view. Edges of the second color filter CF2 may partially cover the upper surface of the light blocking member BM, but the present disclosure is not limited thereto. The second color filter CF2 may selectively transmit light of the second color (e.g., green light) and block or absorb light of the first color (e.g., red light) and light of the third color (e.g., blue light). For example, the second color filter CF2 may be a green color filter and may include a green colorant.

The third color filter CF3 may be disposed on the third insulating layer IL3 in the third emission area EA3. The third color filter CF3 may be surrounded by the light blocking member BM in a plan view. Edges of the third color filter CF3 may partially cover the upper surface of the light blocking member BM, but the present disclosure is not limited thereto. The third color filter CF3 may selectively transmit light of the third color (e.g., blue light) and block or absorb light of the first color (e.g., red light) and light of the second color (e.g., green light). For example, the third color filter CF3 may be a blue color filter and may include a blue colorant.

The first through third color filters CF1 through CF3 may absorb a part of light coming from the outside of the display device 10, thereby reducing reflected light due to the external light. Therefore, the first through third color filters CF1 through CF3 can prevent or substantially reduce color distortion due to reflection of external light.

The planarization layer OC may be disposed on the light blocking member BM and the first through third color filters CF1 through CF3. The planarization layer OC may planarize an upper end of the color filter layer CFL. For example, the planarization layer OC may include an organic insulating material.

FIGS. 7 to 13 are cross-sectional views illustrating a process of manufacturing a display device according to some embodiments of the present disclosure.

In FIG. 7, first through third cathode electrodes CE1 through CE3 may be spaced apart from each other on a transistor layer TFTL. The first through third cathode electrodes CE1 through CE3 may include at least one of silver (Ag), titanium (Ti), copper (Cu), aluminum (Al), nickel (Ni), and lanthanum (La). The first through third cathode electrodes CE1 through CE3 may be reflective electrodes including a material having high reflectivity. The first through third cathode electrodes CE1 through CE3 may have a thickness of about 600 angstroms (Å) or more, but the present disclosure is not limited thereto.

The first electron transporting layer ETL1 may be disposed on the first cathode electrode CE1 in the first emission area EA1. The second electron transporting layer ETL2 may be disposed on the second cathode electrode CE2 in the second emission area EA2. The third electron transporting layer ETL3 may be disposed on the third cathode electrode CE3 in the third emission area EA3. For example, the first through third electron transporting layer ETL1 through ETL3 may include ytterbium (Yb) or zinc (Zn), but the present disclosure is not limited thereto.

A sacrificial layer SFL may be disposed on the first through third electron transporting layer ETL1 through ETL3. The sacrificial layer SFL may be disposed between upper surfaces of the first through third electron transporting layer ETL1 through ETL3 and a first insulating layer IL1. The sacrificial layer SFL may include an oxide semiconductor. For example, the sacrificial layer SFL may include at least one of indium gallium zinc oxide (IGZO), zinc tin oxide (ZTO), and indium zinc oxide (IZO).

The first insulating layer IL1 may be disposed on the transistor layer TFTL and the sacrificial layer SFL. The first insulating layer IL1 may include an inorganic insulating material. The first insulating layer IL1 may include, but is not limited to, at least one of a silicon nitride layer, a silicon oxynitride layer, a silicon oxide layer, a titanium oxide layer, an aluminum oxide layer, and an amorphous silicon layer.

The first bank BNK1 may be disposed on the first insulating layer IL1, and the second bank BNK2 may be disposed on the first bank BNK1. A thickness of the first bank BNK1 may be greater than a thickness of the second bank BNK2. The first bank BNK1 may include a metal material having high electrical conductivity, and the second bank BNK2 may include a material having low reflectivity. For example, the first bank BNK1 may include aluminum (Al), and the second bank BNK2 may include titanium (Ti). However, the present disclosure is not limited thereto.

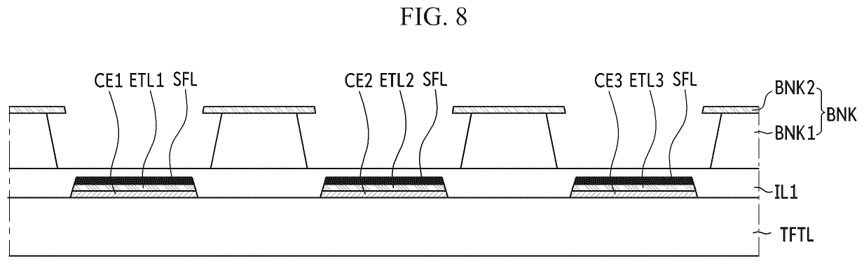

In FIG. 8, the second bank BNK2 and the first bank BNK1 may be sequentially etched to form a plurality of holes. The holes may overlap the first through third emission areas EA1 through EA3. The first and second banks BNK1 and BNK2 may be etched by performing at least one of a dry etching process and a wet etching process. The first and second banks BNK1 and BNK2 may include different metal materials, and etching rates of the first and second banks BNK1 and BNK2 may be different from each other. The etching rate of the first bank BNK1 may be higher than that of the second bank BNK2, and the first bank BNK1 may be etched more than the second bank BNK2. Therefore, the side shape of the first and second banks BNK1 and BNK2 may be determined by a difference in etching rate between the first and second banks BNK1 and BNK2. The second bank BNK2 may include tips protruding from the first bank BNK1 toward the holes. Side surfaces of the first bank BNK1 may be recessed inward from side surfaces of the second bank BNK2. An undercut structure may be formed under the tips of the second bank BNK2. The thickness of the first bank BNK1 may be greater than that of the second bank BNK2.

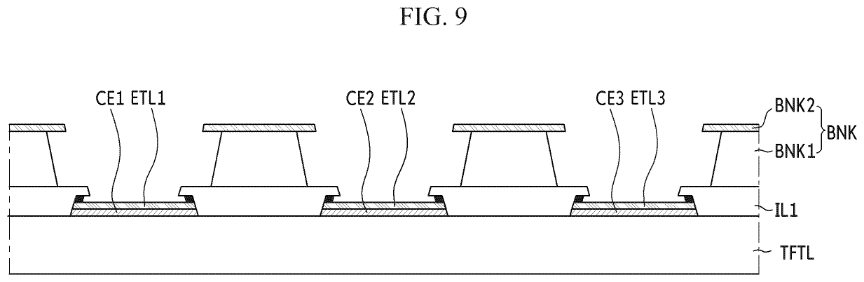

In FIG. 9, the first insulating layer IL1 and the sacrificial layer SFL may be etched by performing at least one of a dry etching process and a wet etching process. As the first insulating layer IL1 and the sacrificial layer SFL are etched, at least a portion of the upper surface of each of the first through third electron transporting layer ETL1 through ETL3 may be exposed. An etching rate of the sacrificial layer SFL may be higher than an etching rate of the first insulating layer IL1. The sacrificial layer SFL may be etched more than the first insulating layer IL1 in a plan view. When the sacrificial layer SFL is etched, a residual pattern RP (see, e.g., FIG. 5) may remain between the first insulating layer IL1 and the first electron transporting layer ETL1. An undercut structure may be formed under the first insulating layer IL1. Accordingly, side surfaces of the residual pattern RP may be recessed inward from side surfaces of the first insulating layer IL1.

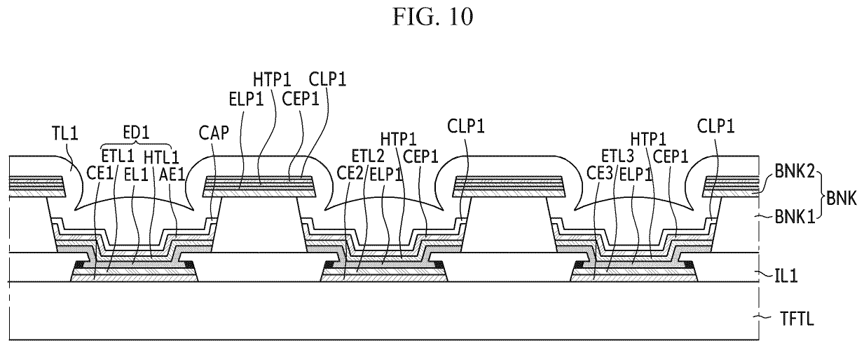

In FIG. 10, a first light emitting layer EL1 may be directly disposed on the first electron transporting layer ETL1 in the first emission area EA1. A portion of the first light emitting layer EL1 may fill a space surrounded by the first electron transporting layer ETL1, the residual pattern RP and the first insulating layer IL1, and another portion of the first light emitting layer EL1 may cover a portion of an upper surface of the first insulating layer IL1 and the side surfaces of the first insulating layer IL1.

An organic material for forming the first light emitting layer EL1 and a first organic pattern ELP1 may be deposited on the entire surface of the display device 10. The first light emitting layer EL1 and the first organic pattern ELP1 may be deposited in the same process, but may be cut and separated by the tips of the second bank BNK2. A portion of the first organic pattern ELP1 may be disposed on the second bank BNK2. The other portion of the first organic pattern ELP1 may be disposed on the second electron transporting layer ETL2 in the second emission area EA2 and may be disposed on the third electron transporting layer ETL3 in the third emission area EA3.

A first hole transporting layer HTL1 may be disposed on the first light emitting layer EL1 in the first emission area EA1. Material for forming a first hole transporting layer HTL1 and a first hole pattern HTP1 may be deposited on the entire surface of the display device 10. The first hole transporting layer HTL1 and the first hole pattern HTP1 may be deposited in the same process, but may be cut and separated by the tips of the second bank BNK2. A portion of the first hole pattern HTP1 may be disposed on the first organic pattern ELP1 on the second bank BNK2. Another portion of the first hole pattern HTP1 may be disposed on the first organic pattern ELP1 in the second and third emission areas EA2 and EA3. Accordingly, the first hole pattern HTP1 may be disposed on the first organic pattern ELP1 in an area excluding the first emission area EA1.

A first anode electrode AE1 may be disposed on the first hole transporting layer HTL1 in the first emission area EA1. Metal material for forming the first anode electrode AE1 and a first electrode pattern CEP1 may be deposited on the entire surface of the display device 10. The first anode electrode AE1 and the first electrode pattern CEP1 may be deposited in the same process, but may be cut and separated by the tips of the second bank BNK2. A portion of the first electrode pattern CEP1 may be disposed on the first hole pattern HTP1 on the second bank BNK2. Another portion of the first electrode pattern CEP1 may be disposed on the first hole pattern HTP1 in the second and third emission areas EA2 and EA3. Accordingly, the first electrode pattern CEP1 may be disposed on the first hole pattern HTP1 in an area excluding the first emission area EA1.

A capping layer CAP may be disposed on the first anode electrode AE1 in the first emission area EA1. Inorganic material for forming the capping layer CAP and a first capping pattern CLP1 may be deposited on the entire surface of the display device 10. The capping layer CAP and the first capping pattern CLP1 may be deposited in the same process, but may be cut and separated by the tips of the second bank BNK2. A portion of the first capping pattern CLP1 may be disposed on the first electrode pattern CEP1 on the second bank BNK2. The other portion of the first capping pattern CLP1 may be disposed on the first electrode pattern CEP1 in the second and third emission areas EA2 and EA3. Accordingly, the first capping pattern CLP1 may be disposed on the first electrode pattern CEP1 in an area excluding the first emission area EA1.

An inorganic material for forming a first inorganic layer TL1 may be deposited on the entire surface of the display device 10. The first inorganic layer TL1 may cover an upper surface of the capping layer CAP in the first emission area EA1 and may cover an upper surface of the first capping pattern CLP1 in the area excluding the first emission area EA1. The first inorganic layer TL1 may cover the side surfaces of the first bank BNK1, lower and side surfaces of the tips of the second bank BNK2, the side surfaces of the first organic pattern ELP1 on the second bank BNK2, the side surfaces of the first hole pattern HTP1, the side surfaces of the first electrode pattern CEP1, and the upper and side surfaces of the first capping pattern CLP1. The first inorganic layer TL1 may include an inorganic material to prevent oxygen or moisture from penetrating (or substantially reduce the amount of oxygen or moisture penetrating) into the first light emitting element ED1. The first inorganic layer TL1 may be an inorganic encapsulation layer.

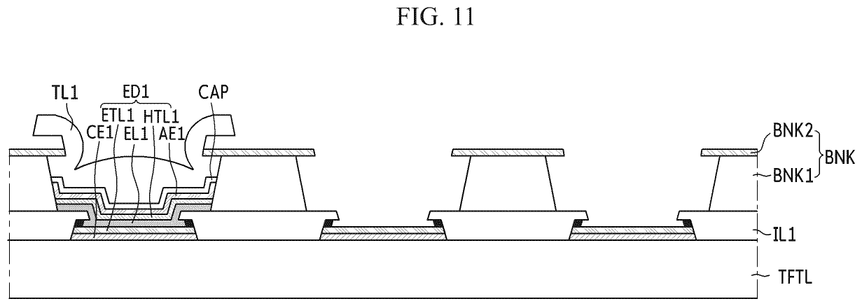

In FIG. 11, the first inorganic layer TL1, the first capping pattern CLP1, the first electrode pattern CEP1, the first hole pattern HTP1, and the first organic pattern ELP1 not disposed in the first emission area EA1 (see, e.g., FIG. 10) may be etched through an etching process. For example, the first inorganic layer TL1, the first capping pattern CLP1, the first electrode pattern CEP1, the first hole pattern HTP1, and the first organic pattern ELP1 may be etched by performing at least one of a dry etching process and a wet etching process. Accordingly, the second electron transporting layer ETL2 may be exposed in the second emission area EA2, and the third electron transporting layer ETL3 may be exposed in the third emission area EA3.

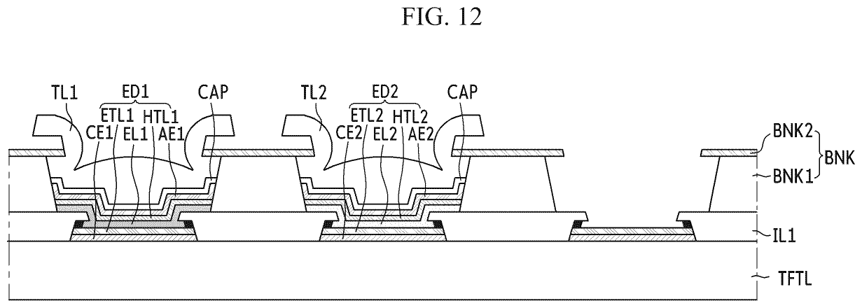

In FIG. 12, a second light emitting layer EL2 may be disposed on the second electron transporting layer ETL2 in the second emission area EA2 by repeating the proceeded process in FIGS. 10 and 11. A portion of the second light emitting layer EL2 may fill a space surrounded by the second electron transporting layer ETL2, the residual patterns RP and the first insulating layer IL1, and the other portion of the second light emitting layer EL2 may cover the upper and side surfaces of the first insulating layer IL1.

The second hole transporting layer HTL2 may be disposed on the second light emitting layer EL2 in the second emission area EA2. The second anode electrode AE2 may be disposed on the second hole transporting layer HTL2. The capping layer CAP may be disposed on the second anode electrode AE2. The second inorganic layer TL2 may cover the upper surface of the capping layer CAP, the side surfaces of the first bank BNK1, and the lower and side surfaces of the tip of the second bank BNK2 in the second emission area EA2.

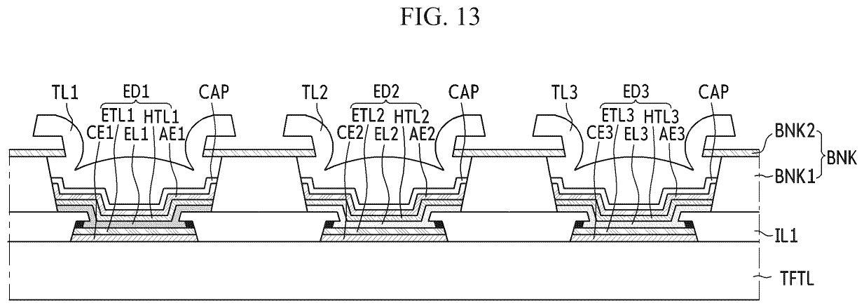

In FIG. 13, a third light emitting layer EL3 may be disposed on the third electron transporting layer ETL3 in the third emission area EA3 by repeating the proceeded process in FIGS. 10 and 11. A portion of the third light emitting layer EL3 may fill a space surrounded by the third electron transporting layer ETL3, the residual patterns RP and the first insulating layer IL1, and the other portion of the third light emitting layer EL3 may cover the upper and side surfaces of the first insulating layer IL1.

The third hole transporting layer HTL3 may be disposed on the third light emitting layer EL3 in the third emission area EA3. The third anode electrode AE3 may be disposed on the third hole transporting layer HTL3. The capping layer CAP may be disposed on the third anode electrode AE3. The third inorganic layer TL3 may cover the upper surface of the capping layer CAP, the side surfaces of the first bank BNK1, and the lower and side surfaces of the tip of the second bank BNK2 in the third emission area EA3.

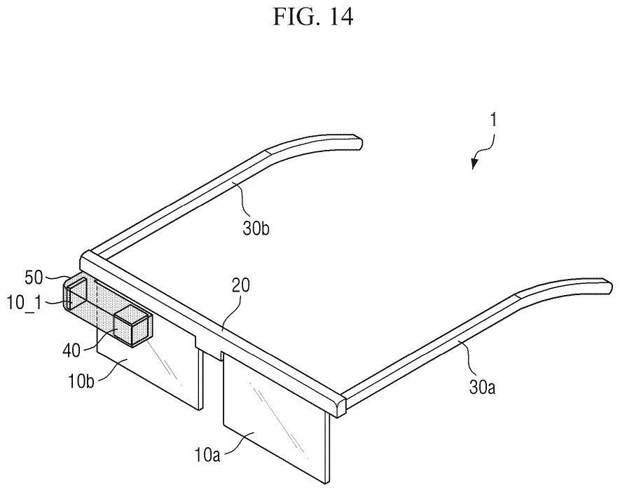

FIG. 14 illustrates a virtual reality device including a display device according to some embodiments of the present disclosure. A display device 10_1 of FIG. 14 may include any one of the display devices 10 according to the embodiments of FIGS. 1 through 6 described above.

Referring to FIG. 14, the virtual reality device 1 may be a glasses-type display. The virtual reality device 1 may include the display device 10_1, a left lens 10a, a right lens 10b, a support frame 20, eyeglass frame legs 30a and 30b, a reflective member 40, and a display device housing 50.

In some examples, the virtual reality device 1 may be applied to a head mounted display including a head mounted band that can be worn on the head instead of the eyeglass frame legs 30a and 30b. Therefore, the virtual reality device 1 is not limited to the one illustrated in FIG. 14 and can be applied in various forms to various other electronic devices.

The display device housing 50 may include the display device 10_1 and the reflective member 40. An image displayed on the display device 10_1 may be reflected by the reflective member 40 and provided to a user's right eye through the right lens 10b. Accordingly, the user can view a virtual reality image displayed on the display device 10_1 through the right eye.

The display device housing 50 may be disposed at a right end of the support frame 20. However, the position of the display device housing 50 is not limited thereto. For example, the display device housing 50 may also be disposed at a left end of the support frame 20. In this case, an image displayed on the display device 10_1 may be reflected by the reflective member 40 and provided to the user's left eye through the left lens 10a. Therefore, the user can view a virtual reality image displayed on the display device 10_1 through the left eye.

For another example, the display device housing 50 may be disposed at both the left and right ends of the support frame 20. In this case, the user can view a virtual reality image displayed on the display device 10_1 through both the left and right eyes.

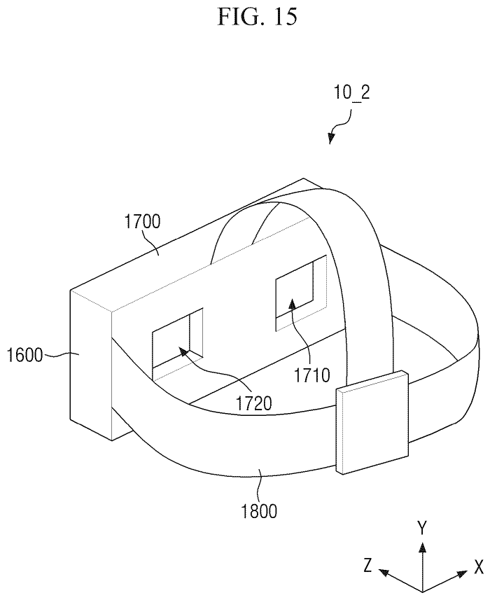

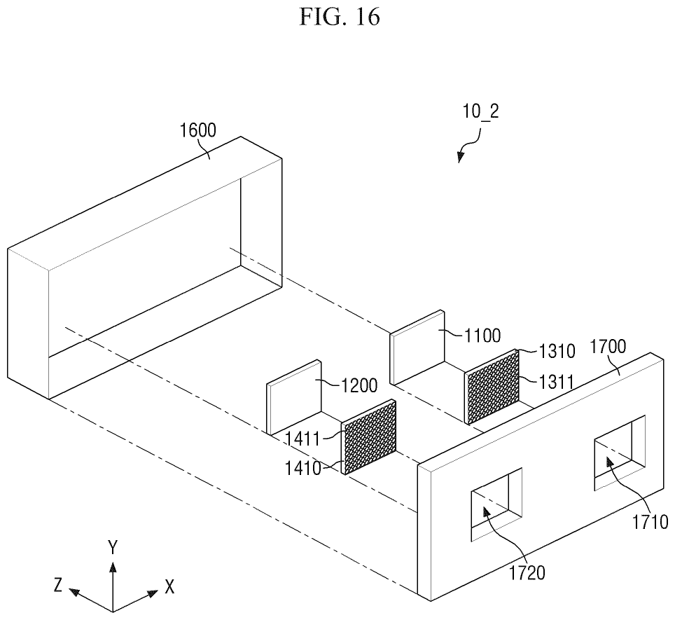

FIGS. 15 and 16 illustrate a head mounted display including a display device according to some embodiments of the present disclosure. A display device 10_2 of FIGS. 15 and 16 may include any one of the display devices 10 according to the embodiments of FIGS. 1 through 6 described above.

Referring to FIGS. 15 and 16, the display device 10_2 may be applied to a head mounted display (HMD). A first display device 1100 may provide an image to a user's right eye, and a second display device 1200 may provide an image to the user's left eye.

A first lens array 1310 may be disposed between the first display device 1100 and a housing cover 1700. The first lens array 1310 may include a plurality of lenses 1311. The lenses 1311 may include convex lenses that are convex toward the housing cover 1700.

A second lens array 1410 may be disposed between the second display device 1200 and the housing cover 1700. The second lens array 1410 may include a plurality of lenses 1411. The lenses 1411 may include convex lenses that are convex toward the housing cover 1700.

A display panel housing 1600 may house the first display device 1100, the second display device 1200, the first lens array 1310, and the second lens array 1410. A surface of the display panel housing 1600 may be open to accommodate the first display device 1100, the second display device 1200, the first lens array 1310, and the second lens array 1410.

The housing cover 1700 may cover the open surface of the display panel housing 1600. The housing cover 1700 may include a first opening 1710 at which a user's right eye is positioned and a second opening 1720 at which the user's left eye is positioned. For example, the first opening 1710 and the second opening 1720 may be formed in a square shape, but the shapes of the first and second openings 1710 and 1720 are not limited thereto. For another example, the first and second openings 1710 and 1720 may be formed in a circular or oval shape. For another example, the first and second openings 1710 and 1720 may be integrated to form one opening.

The first opening 1710 may be aligned with the first display device 1100 and the first lens array 1310, and the second opening 1720 may be aligned with the second display device 1200 and the second lens array 1410. Therefore, a user can view an image of the first display device 1100, which is enlarged as a virtual image by the first lens array 1310, through the first opening 1710 and can view an image of the second display device 1200, which is enlarged as a virtual image by the second lens array 1410, through the second opening 1720.

A head mounted band 1800 may fix the display panel housing 1600 to a user's head so that the first opening 1710 and the second opening 1720 of the housing cover 1700 are placed on the user's right and left eyes, respectively. The head mounted band 1800 may be connected to upper, left, and right surfaces of the display panel housing 1600.

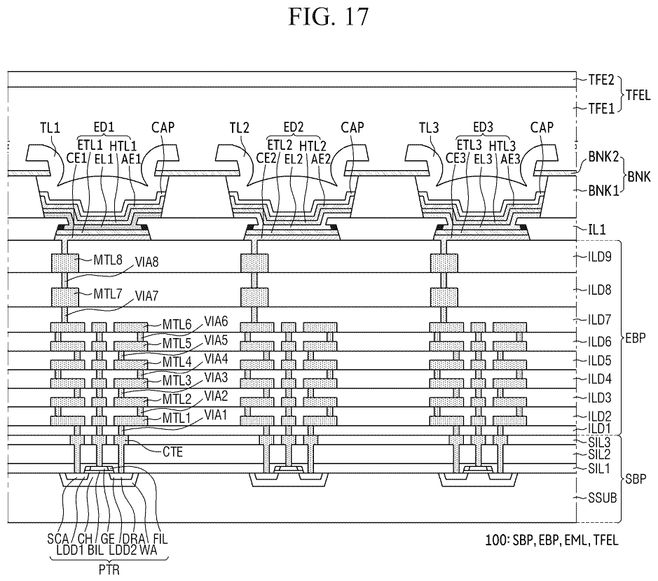

FIG. 17 is a cross-sectional view illustrating pixels in the display devices of FIGS. 14 through 16 according to some embodiments of the present disclosure. A display device of FIG. 17 may include the light emitting element layer EML and the encapsulation layer TFEL of FIG. 5 as they are. The same elements as those described above will be briefly described or will not be described.

Referring to FIG. 17, a display panel 100 may include a semiconductor backplane SBP, an emission backplane EBP, the light emitting element layer EML (see, e.g., FIG. 5), and the encapsulation layer TFEL.

The semiconductor backplane SBP may include a semiconductor substrate SSUB, first through third semiconductor insulating layers SIL1 through SIL3, and contact terminals CTE.

The semiconductor substrate SSUB may be a silicon substrate, a germanium substrate, or a silicon-germanium substrate. The semiconductor substrate SSUB may be a substrate doped with first-type impurities. A plurality of well areas WA may be disposed in an upper surface of the semiconductor substrate SSUB. The well areas WA may be areas doped with second-type impurities different from the first-type impurities. For example, when the first-type impurities are p-type impurities, the second-type impurities may be n-type impurities. For another example, when the first-type impurities are n-type impurities, the second-type impurities may be p-type impurities.

The semiconductor substrate SSUB may include a plurality of pixel transistors PTR. Each of the pixel transistors PTR may include a well area WA, a source area SCA, a drain area DRA, a channel area CH, a first lightly doped impurity area LDD1, a second lightly doped impurity area LDD2, a bottom insulating layer BIL, a gate electrode GE, and a side insulating layer FIL.

The well area WA may be disposed in an upper part of the semiconductor substrate SSUB. The well area WA may accommodate the source area SCA, the drain area DRA, the channel area CH, the first lightly doped impurity area LDD1, and the second lightly doped impurity area LDD2.

The source area SCA may correspond to a source electrode of a pixel transistor PTR, and the drain area DRA may correspond to a drain electrode of the pixel transistor PTR. Each of the source area SCA and the drain area DRA may be doped with the first-type impurities. The source area SCA may be disposed on a side of the gate electrode GE, and the drain area DRA may be disposed on the other side of the gate electrode GE.

The channel area CH may be disposed between the source area SCA and the drain area DRA. The bottom insulating layer BIL may be disposed on the channel area CH to insulate the channel area CH from the gate electrode GE. The gate electrode GE may be disposed on the bottom insulating layer BIL. The gate electrode GE may overlap with the channel area CH and the well area WA in the thickness direction. The side insulating layer FIL may be disposed on side surfaces of the gate electrode GE and an upper surface of the bottom insulating layer BIL.

The first lightly doped impurity area LDD1 may be disposed between the channel area CH and the source area SCA, and the second lightly doped impurity area LDD2 may be disposed between the channel area CH and the drain area DRA. The first lightly doped impurity area LDD1 may have a lower impurity concentration than the source area SCA due to the bottom insulating layer BIL. The second lightly doped impurity area LDD2 may have a lower impurity concentration than the drain area DRA due to the bottom insulating layer BIL. A distance between the source area SCA and the drain area DRA may be increased by the first lightly doped impurity area LDD1 and the second lightly doped impurity area LDD2. Accordingly, a length of the channel area CH of the pixel transistor PTR may increase, thereby preventing (or substantially reducing the likelihood of) punch-through and hot carrier phenomena caused by a short channel.

A first semiconductor insulating layer SIL1 may be disposed on the semiconductor substrate SSUB. The first semiconductor insulating layer SIL1 may include, but is not limited to, a silicon carbon nitride (SiCN) or silicon oxide (SiOx)-based inorganic layer.

A second semiconductor insulating layer SIL2 may be disposed on the first semiconductor insulating layer SIL1. The second semiconductor insulating layer SIL2 may include, but is not limited to, a silicon oxide (SiOx)-based inorganic layer.

The contact terminals CTE may be disposed on the second semiconductor insulating layer SIL2. Each of the contact terminals CTE may be connected to one of the gate electrode GE, the source area SCA, and the drain area DRA of a pixel transistor PTR through a hole penetrating the first semiconductor insulating layer SIL1 and the second semiconductor insulating layer SIL2. The contact terminals CTE may include at least one of copper (Cu), aluminum (Al), tungsten (W), molybdenum (Mo), chromium (Cr), gold (Au), titanium (Ti), nickel (Ni), and neodymium (Nd).

A third semiconductor insulating layer SIL3 may be disposed on side surfaces of each of the contact terminals CTE. An upper surface of each of the contact terminals CTE may be exposed without being covered by the third semiconductor insulating layer SIL3. The third semiconductor insulating layer SIL3 may include, but is not limited to, a silicon oxide (SiOx)-based inorganic layer.

The emission backplane EBP may include first through eighth metal layers MTL1 through MTL8, first through eighth vias VIA1 through VIA8, and first through ninth interlayer insulating layers ILD1 through ILD9.

The first through eighth metal layers MTL1 through MTL8 may be electrically connected to the contact terminals CTE exposed in the semiconductor backplane SBP to form each pixel circuit. For example, the semiconductor backplane SBP may include a plurality of pixel transistors PTR, and the emission backplane EBP may include a connection electrode connecting the pixel transistors PTR and at least one capacitor connected to each of the pixel transistors PTR. The emission backplane EBP may electrically connect a pixel circuit to a first light emitting element ED1.

The first interlayer insulating layer ILD1 may be disposed on the semiconductor backplane SBP. The first vias VIA1 may penetrate the first interlayer insulating layer ILD1 and may be connected to the contact terminals CTE exposed in the semiconductor backplane SBP. The first metal layers MTL1 may be disposed on the first interlayer insulating layer ILD1 and connected to the first vias VIA1.

The second interlayer insulating layer ILD2 may be disposed on the first interlayer insulating layer ILD1 and the first metal layers MTL1. The second vias VIA2 may penetrate the second interlayer insulating layer ILD2 and may be connected to the first metal layers MTL1. The second metal layers MTL2 may be disposed on the second interlayer insulating layer ILD2 and connected to the second vias VIA2.

The third interlayer insulating layer ILD3 may be disposed on the second interlayer insulating layer ILD2 and the second metal layers MTL2. The third vias VIA3 may penetrate the third interlayer insulating layer ILD3 and may be connected to the second metal layers MTL2. The third metal layers MTL3 may be disposed on the third interlayer insulating layer ILD3 and connected to the third vias VIA3.

The fourth interlayer insulating layer ILD4 may be disposed on the third interlayer insulating layer ILD3 and the third metal layers MTL3. The fourth vias VIA4 may penetrate the fourth interlayer insulating layer ILD4 and may be connected to the third metal layers MTL3. The fourth metal layers MTL4 may be disposed on the fourth interlayer insulating layer ILD4 and connected to the fourth vias VIA4.

The fifth interlayer insulating layer ILD5 may be disposed on the fourth interlayer insulating layer ILD4 and the fourth metal layers MTL4. The fifth vias VIA5 may penetrate the fifth interlayer insulating layer ILD5 and may be connected to the fourth metal layers MTL4. The fifth metal layers MTL5 may be disposed on the fifth interlayer insulating layer ILD5 and connected to the fifth vias VIA5.

The sixth interlayer insulating layer ILD6 may be disposed on the fifth interlayer insulating layer ILD5 and the fifth metal layers MTL5. The sixth vias VIA6 may penetrate the sixth interlayer insulating layer ILD6 and may be connected to the fifth metal layers MTL5. The sixth metal layers MTL6 may be disposed on the sixth interlayer insulating layer ILD6 and connected to the sixth vias VIA6.

The seventh interlayer insulating layer ILD7 may be disposed on the sixth interlayer insulating layer ILD6 and the sixth metal layers MTL6. The seventh vias VIA7 may penetrate the seventh interlayer insulating layer ILD7 and may be connected to the sixth metal layers MTL6. The seventh metal layers MTL7 may be disposed on the seventh interlayer insulating layer ILD7 and connected to the seventh vias VIA7.

The eighth interlayer insulating layer ILD8 may be disposed on the seventh interlayer insulating layer ILD7 and the seventh metal layers MTL7. The eighth vias VIA8 may penetrate the eighth interlayer insulating layer ILD8 and may be connected to the seventh metal layers MTL7. The eighth metal layers MTL8 may be disposed on the eighth interlayer insulating layer ILD8 and connected to the eighth vias VIA8. The ninth interlayer insulating layer ILD9 may be disposed on the eighth interlayer insulating layer ILD8 and the eighth metal layers MTL8.

The first through eighth metal layers MTL1 through MTL8 and the first through eighth vias VIA1 through VIA8 may include substantially the same material. The first through eighth metal layers MTL1 through MTL8 and the first through eighth vias VIA1 through VIA8 may include at least one of copper (Cu), aluminum (Al), tungsten (W), molybdenum (Mo), chromium (Cr), gold (Au), titanium (Ti), nickel (Ni), and neodymium (Nd). Each of the first through ninth interlayer insulating layers ILD1 through ILD9 may include, but is not limited to, a silicon oxide (SiOx)-based inorganic layer.

The display device 10 may include a large number of pixels SP in a relatively small area as its resolution increases. The emission backplane EBP including the first through eighth metal layers MTL1 through MTL8 may implement a connection electrode connecting the pixel transistors PTR and at least one capacitor connected to each of the pixel transistors PTR, thereby implementing pixel circuits in a relatively small area. Therefore, the light emitting element layer EML can be formed on a silicon wafer (Si-wafer) including the semiconductor backplane SBP and the emission backplane EBP, and the display device 10 can realize ultra-high resolution image quality.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a pixel circuit comprising a transistor on a substrate;
a first cathode electrode electrically connected to the pixel circuit and in a first emission area;
a first electron transporting layer on the first cathode electrode;
an insulating layer covering an edge of the first electron transporting layer;
a first light emitting layer on the first electron transporting layer and the insulating layer;
a first hole transporting layer on the first light emitting layer;
a first anode electrode on the first hole transporting layer;
a first bank on the insulating layer, surrounding the first emission area and in contact with the first anode electrode; and
a second bank on the first bank and comprising a tip protruding from a side surface of the first bank toward the first emission area.

2. The display device of claim 1, wherein the first anode electrode receives a driving voltage through the first bank.

3. The display device of claim 1, further comprising:
a first capping layer on the first anode electrode; and
a first inorganic layer covering an upper surface of the first capping layer, the side surface of the first bank, and the lower and side surfaces of the tip of the second bank.

4. The display device of claim 3, wherein the first inorganic layer has a cavity structure spaced apart from the upper surface of the second bank.

5. The display device of claim 1, wherein the first electron transporting layer comprises ytterbium (Yb) or zinc (Zn), and the first hole transporting layer comprises nickel (Ni).

6. The display device of claim 5, wherein the first cathode electrode is a reflective electrode comprising material having a high reflectivity, and
wherein the first anode electrode is translucent or transparent.

7. The display device of claim 1, further comprising:
a second cathode electrode in a second emission area of the substrate;
a second electron transporting layer on the second cathode electrode;
a second light emitting layer on the second electron transporting layer;
a second hole transporting layer on the second light emitting layer; and
a second anode electrode on the second hole transporting layer to be in contact with the side surface of the first bank.

8. The display device of claim 7, wherein the first and second anode electrodes are electrically connected through the first bank to receive a driving voltage.

9. The display device of claim 7, further comprising:
a second capping layer on the second anode electrode; and
a second inorganic layer covering an upper surface of the second capping layer, and the lower and side surfaces of the tip of the second bank.

10. The display device of claim 7, further comprising:
a third cathode electrode in a third emission area of the substrate;
a third electron transporting layer on the third cathode electrode;
a third light emitting layer on the third electron transporting layer;
a third hole transporting layer on the third light emitting layer; and
a third anode electrode on the third hole transporting layer to be in contact with the side surface of the first bank.

11. The display device of claim 1, wherein the pixel circuit comprises:
an active region, a drain electrode, and a source electrode of the transistor on the substrate;
a gate electrode of the transistor in the active region of the transistor;
a first connection electrode on the gate electrode and connected to the drain electrode of the transistor; and
a second connection electrode on the first connection electrode and electrically connecting the first cathode electrode and the first connection electrode.

12. The display device of claim 1, wherein the pixel circuit comprises:
a well area of a pixel transistor on a top portion of a semiconductor substrate;
a drain area on a first side of the well area;
a source area on a second side of the well area;
a channel area between the drain area and the source area;
a first low concentration impurity area between the channel area and the source area;
a second low concentration impurity area between the channel area and the drain area;
a contact terminal connected to the source area; and
a metal layer electrically connecting the contact terminal and the first cathode electrode.

13. A method of manufacturing a display device, the method comprising:
forming a first cathode electrode overlapping with a first emission area and a second cathode electrode overlapping with a second emission area on a substrate;
forming a first electron transporting layer on the first cathode electrode, and forming a second electron transporting layer on the second cathode electrode;
sequentially stacking a sacrificial layer, an insulating layer, a first bank, and a second bank on the first and second electron transporting layers;
etching the second bank and the first bank to form a tip of the second bank protruding from a side surface of the first bank;
etching the insulating layer and the sacrificial layer to expose the first and second electron transporting layer;
forming a first light emitting layer on the first electron transporting layer and forming a first organic pattern in an area excluding the first electron transporting layers;
forming a first hole transporting layer on the first light emitting layer and forming a first hole pattern on the first organic pattern; and
forming a first anode electrode in contact with the side surface of the first bank on the first hole transporting layer and forming a first electrode pattern on the first hole pattern.

14. The method of claim 13, wherein the first electron transporting layer comprises ytterbium (Yb) or zinc (Zn), and
wherein the first hole transporting layer comprises nickel (Ni).

15. The method of claim 13, wherein the first cathode electrode is a reflective electrode containing material having a high reflectivity, and
wherein the first anode electrode is transparent or translucent.

16. The method of claim 13, further comprising:
forming a first capping layer on the first anode electrode and forming a first capping pattern on the first electrode pattern; and
forming a first inorganic layer covering the upper surface of the first capping layer, the side surface of the first bank, and the lower and side surfaces of the tip of the second bank.

17. The method of claim 16, further comprising etching the first inorganic layer, the first capping pattern, the first electrode pattern, the first hole pattern, and the first organic pattern not overlapping the first emission area.

18. The method of claim 17, further comprising:
forming a second light emitting layer on the second electron transporting layer;
forming a second hole transporting layer on the second light emitting layer;
forming a second anode electrode in contact with the side surface of the first bank on the second hole transporting layer;
forming a second capping layer on the second anode electrode; and
forming a second inorganic layer covering the upper surface of the second capping layer, the side surface of the first bank, and the lower and the side surfaces of the tip of the second bank.

19. The method of claim 18, wherein the first and second anode electrodes and the first bank are electrically connected.

20. The method of claim 18, further comprising:
forming a third cathode electrode overlapping a third emission area on the substrate;
forming a third electron transporting layer on the third cathode electrode;
forming a third light emitting layer on the third electron transporting layer;
forming a third hole transporting layer on the third hole transporting layer;
forming a third anode electrode in contact with the side surface of the first bank on the third hole transporting layer;
forming a third capping layer on the third anode electrode; and
forming a third inorganic layer covering the upper surface of the third capping layer, the side surface of the first bank, and the lower and side surfaces of the tip of the second bank.

21. An electronic device comprising:
a display device comprising:
a pixel circuit comprising a transistor on a substrate;
a first cathode electrode electrically connected to the pixel circuit and in a first emission area;
a first electron transporting layer on the first cathode electrode;
an insulating layer covering an edge of the first electron transporting layer;
a first light emitting layer on the first electron transporting layer and the insulating layer;
a first hole transporting layer on the first light emitting layer;
a first anode electrode on the first hole transporting layer;
a first bank on the insulating layer, surrounding the first emission area and in contact with the first anode electrode; and
a second bank on the first bank and comprising a tip protruding from a side surface of the first bank toward the first emission area; and
a housing configured to receive the display device.

22. A head-mounted electronic device comprising:
a display device comprising:
a pixel circuit comprising a transistor on a substrate;
a first cathode electrode electrically connected to the pixel circuit and in a first emission area;
a first electron transporting layer on the first cathode electrode;
an insulating layer covering an edge of the first electron transporting layer;
a first light emitting layer on the first electron transporting layer and the insulating layer;
a first hole transporting layer on the first light emitting layer;
a first anode electrode on the first hole transporting layer;
a first bank on the insulating layer, surrounding the first emission area and in contact with the first anode electrode; and
a second bank on the first bank and comprising a tip protruding from a side surface of the first bank toward the first emission area, and
a head mounted display comprising:
a first lens array;
a second lens array; and
a display panel housing configured to receive the display device,
wherein the first and second lens arrays are configured to display an image of the display device to each of a user's eyes.
